(19) United States
(12) Patent Application Publication
(10) Pub. No.: US 2026/0027493 A1
(43) Pub. Date: Jan. 29, 2026

(54) LIQUID IMMERSION COOLING SYSTEM AND REMOVAL METHOD

(71) Applicant: MITSUBISHI HEAVY INDUSTRIES, LTD., Tokyo (JP)

(72) Inventors: Taisuke Tsukamoto, Tokyo (JP); Kohei Kanamori, Tokyo (JP); Shinichi Okamoto, Tokyo (JP); Naoki Ogawa, Tokyo (JP); Hidetaka Kafuku, Tokyo (JP); Shuji Fujii, Tokyo (JP); Nobuhide Hara, Tokyo (JP)

(73) Assignee: MITSUBISHI HEAVY INDUSTRIES, LTD., Tokyo (JP)

(21) Appl. No.: 19/099,233

(22) PCT Filed: Feb. 17, 2023
(86) PCT No.: PCT/JP2023/005841

§ 371 Date: Jan. 28, 2025

(30) Foreign Application Priority Data
Aug. 26, 2022 (JP) 2022-134840

(51) Int. Cl. B01D 15/00; B01J 20/20; H05K 7/20

(52) U.S. Cl. CPC B01D 15/00; B01J 20/20; H05K 7/20772

(57) ABSTRACT

A liquid immersion cooling system, that cools a heat generating body provided on a substrate, includes: a cooling device main body having a casing that houses the substrate and the heat generating body inside and stores a refrigerant for cooling the heat generating body; a circulation flow channel having both ends connected to each other in a communication state in the casing; an adsorption unit that is provided in the circulation flow channel and adsorbs impurities from the refrigerant circulating in the circulation flow channel; a pump that circulates the refrigerant in the circulation flow channel; and a control device that controls the pump. The control device includes a temperature drop detection unit that detects a decrease in temperature of the refrigerant in the casing, and a pump drive unit that drives the pump based on a detection of the temperature drop detection unit.

### TECHNICAL FIELD

The present disclosure relates to a liquid immersion cooling system and a removal method.

This application claims priority to Japanese Patent Application No. 2022-134840, filed in Japan on Aug. 26, 2022, the content of which is incorporated herein by reference.

### BACKGROUND ART

PTL 1 discloses a method for recovering a refrigerant used for liquid immersion cooling. In this method for recovering the refrigerant, the refrigerant is distilled in a distillation tank to separate a low-volatile pollutant from the refrigerant. The distilled refrigerant is recovered in a circulation tank.

### CITATION LIST

### Patent Literature

[PTL 1] U.S. Pat. No. 10,773,192

### SUMMARY OF INVENTION

### Technical Problem

However, in the technique disclosed in PTL 1, in order to prevent the precipitation of impurities such as oil components in a refrigerant, the impurities in the refrigerant are continuously removed during the operation of a liquid immersion cooling device. Therefore, impurities continue to elute from the cable or the like immersed in the refrigerant, and the deterioration of the cable or the like is promoted. In addition, in order to continuously remove the impurities, it is necessary to continuously drive a pump or the like. As a result, this increases costs for power or the like. Therefore, there has been a demand for the development of a technique capable of efficiently removing impurities in a refrigerant.

An object of the present disclosure is to provide a liquid immersion cooling system and a removal method capable of efficiently removing impurities in a refrigerant.

### Solution to Problem

In order to achieve the above object, according to the present disclosure, there is provided a liquid immersion cooling system that cools a heat generating body provided on a substrate, the liquid immersion cooling system including: a cooling device main body having a casing that houses the substrate and the heat generating body inside and stores a refrigerant for cooling the heat generating body; a circulation flow channel having both ends connected to each other in a communication state in the casing; an adsorption unit that is provided in the circulation flow channel and adsorbs impurities from the refrigerant circulating in the circulation flow channel; a pump that circulates the refrigerant in the circulation flow channel; and a control device that controls the pump, in which the control device includes a temperature drop detection unit that detects a decrease in temperature of the refrigerant in the casing, and a pump drive unit that drives the pump based on a detection of the temperature drop detection unit.

According to the present disclosure, there is provided a removal method for removing impurities from a refrigerant used in a liquid immersion cooling system that cools a heat generating body provided on a substrate, in which the liquid immersion cooling system includes a cooling device main body having a casing that houses the substrate and the heat generating body inside and stores the refrigerant, a circulation flow channel having both ends connected to each other in a communication state in the casing, an adsorption unit that is provided in the circulation flow channel and adsorbs the impurities from the refrigerant circulating in the circulation flow channel, and a pump that circulates the refrigerant in the circulation flow channel, and the method includes: a step of detecting a decrease in temperature of the refrigerant in the casing, and a step of driving the pump based on a detection of the decrease in temperature of the refrigerant in the casing.

### Advantageous Effects of Invention

According to the liquid immersion cooling system and the removal method of the present disclosure, it is possible to efficiently remove impurities in a refrigerant.

### BRIEF DESCRIPTION OF DRAWINGS

FIG. 1 is a configuration diagram of a liquid immersion cooling system according to a first embodiment of the present disclosure.

FIG. 2 is a functional block diagram of a control device according to the first embodiment of the present disclosure.

FIG. 3 is a flowchart showing a flow of a removal method according to the first embodiment of the present disclosure.

FIG. 4 is a graph showing a temperature change of a solubility of impurities according to the first embodiment of the present disclosure.

FIG. 5 is a graph showing an adsorption capacity of an adsorbent according to the first embodiment of the present disclosure.

FIG. 6 is a graph showing a decrease in impurity concentration due to driving of a pump according to the first embodiment of the present disclosure.

FIG. 7 is a functional block diagram of a control device according to a first modification example of the first embodiment of the present disclosure.

FIG. 8 is a flowchart showing a flow of a removal method according to a first modification example of the first embodiment of the present disclosure.

FIG. 9 is a configuration diagram of a liquid immersion cooling system according to a second modification example of the first embodiment of the present disclosure.

FIG. 10 is a functional block diagram of a control device according to the second modification example of the first embodiment of the present disclosure.

FIG. 11 is a flowchart showing a flow of a removal method according to a second modification example of the first embodiment of the present disclosure.

FIG. 12 is a configuration diagram of a liquid immersion cooling system according to the second embodiment of the present disclosure.

FIG. 13 is a functional block diagram of a control device according to the second embodiment of the present disclosure.

FIG. 14 is a flowchart illustrating a flow of a removal method according to the second embodiment of the present disclosure.

FIG. 15 is a functional block diagram of a control device according to a modification example of the second embodiment of the present disclosure.

FIG. 16 is a flowchart showing a flow of a removal method according to a modification example of the second embodiment of the present disclosure.

FIG. 17 is a hardware configuration diagram illustrating a configuration of a computer according to each embodiment of the present disclosure.

### DESCRIPTION OF EMBODIMENTS

### First Embodiment

### Liquid Immersion Cooling Device

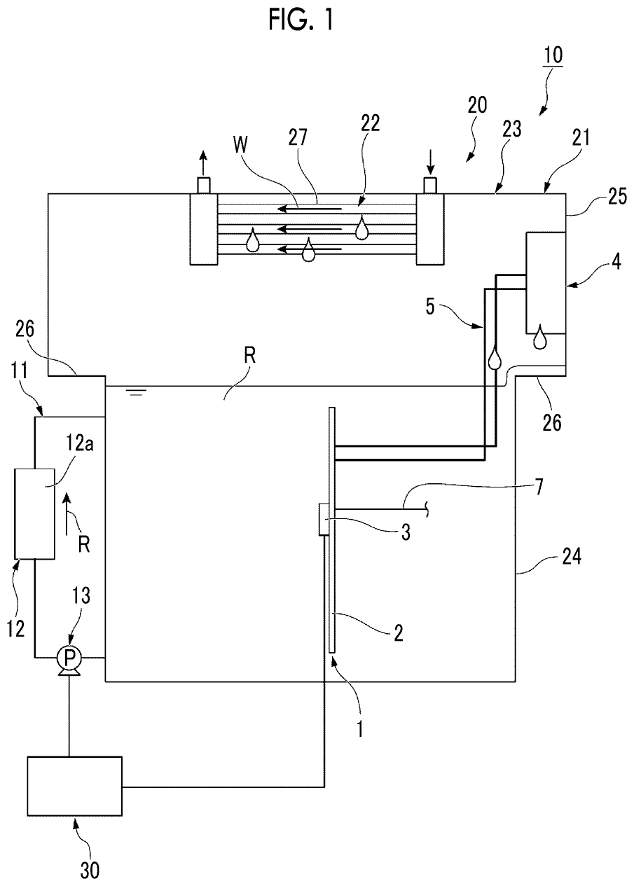

Hereinafter, a liquid immersion cooling system 10 and the removal method according to the first embodiment of the present disclosure will be described with reference to FIGS. 1 to 6.

As shown in FIG. 1, the liquid immersion cooling system 10 is used for cooling electronic equipment. In the present embodiment, the liquid immersion cooling system 10 is used for a server 1 that performs high-speed calculation.

The server 1 includes a print substrate and electronic components such as a chip such as a CPU and a GPU provided on the print substrate. The CPU and the GPU are components responsible for high-speed calculation processing, and thus are subjected to a high load. Therefore, the CPU and the GPU generate heat at a higher temperature than other parts of the server 1.

Hereinafter, the print substrate of the server 1 may be simply referred to as a “substrate 2”, and a chip such as a CPU or a GPU may be referred to as a “heat generating body 3”.

The substrate 2 is formed in a rectangular plate shape. The substrate 2 is disposed in a vertical posture to extend in the up-down direction.

The heat generating body 3 is installed to be attached to the surface of the substrate 2. Therefore, in the present embodiment, the heat generating body 3 is disposed in a vertical posture to extend in the up-down direction similar to the substrate 2.

Power is supplied from a power supply 4 outside the server 1 to the heat generating body 3. The power supply 4 is connected to the substrate 2 by a power supply cable 5. The heat generating body 3 is electrically connected to the power supply 4 via the power supply cable 5 and the substrate 2. In addition, the substrate 2 is connected to an external apparatus (not shown) by a communication cable 7. The communication cable 7 is, for example, a LAN cable. The server 1 communicates with an external apparatus through the communication cable 7.

### Configuration of Liquid Immersion Cooling System

A configuration of the liquid immersion cooling system 10 will be described below.

The liquid immersion cooling system 10 is a device that cools the heat generating body 3 by performing heat exchange between the liquid-phase refrigerant R and the heat generating body 3 in a state where the substrate 2 and the heat generating body 3 are immersed in the liquid-phase refrigerant R. The refrigerant R used in the liquid immersion cooling system 10 is an insulating fluid.

As shown in FIG. 1, the liquid immersion cooling system 10 includes a cooling device 20, a circulation flow channel 11, an adsorption unit 12, a pump 13, and a control device 30.

### Cooling Device

The cooling device 20 includes a cooling device main body 21 and a condensation unit 22. The cooling device main body 21 includes a casing 23.

### Casing

The casing 23 houses the substrate 2 and the heat generating body 3 inside. The liquid-phase refrigerant R is stored in an inner lower portion of the casing 23. In the present embodiment, the entire substrate 2 is immersed in the liquid-phase refrigerant R stored in the casing 23. In the present embodiment, a case where the casing 23 includes a lower casing 24, an upper casing 25, and a connecting wall 26 will be described as an example.

The lower casing 24 is a bottomed container that is open upward. The lower casing 24 is a part of the casing 23 that stores the liquid-phase refrigerant R. The upper casing 25 is provided above the lower casing 24. The upper casing 25 is a bottomed container that is open downward. In the present embodiment, the opening area of the upper casing 25 is larger than the opening area of the lower casing 24. The connecting wall 26 is formed to protrude toward an outer side in the horizontal direction from the opening of the lower casing 24. The connecting wall 26 connects the opening of the lower casing 24 and the opening of the upper casing 25 to each other.

A closed space is formed by the lower casing 24, the upper casing 25, and the connecting wall 26. In the space in the casing 23, the power supply 4, the power supply cable 5, and the communication cable 7 are housed in addition to the substrate 2. The substrate 2 is disposed in the lower casing 24. The substrate 2 is installed at a position floating above the bottom portion of the lower casing 24. The power supply 4 is installed on the connecting wall 26.

The heat generating body 3 is immersed in the liquid-phase refrigerant R stored in the casing 23. Therefore, while the heat generating body 3 generates heat, the heat is supplied to the liquid-phase refrigerant R from the heat generating body 3, and the temperature of the refrigerant R increases. The temperature of the refrigerant R increases to the boiling point and becomes constant. Thereafter, when the heat generating body 3 is stopped, the supply of heat from the heat generating body 3 to the refrigerant R in the casing 23 is stopped. Then, the refrigerant R in the casing 23 is cooled by natural cooling. The temperature of the refrigerant R decreases to a predetermined temperature.

In addition, in the casing 23, the gas-phase refrigerant R is present in addition to the liquid-phase refrigerant R stored in the lower casing 24. The gas-phase refrigerant R is condensed and changes into a liquid phase on the power supply 4 or the power supply cable 5. A part of the power supply cable 5 is immersed in the refrigerant R in the casing 23. In addition, a plasticizer is included in a coating or the like of the cable inside the power supply 4, the power supply cable 5, and the communication cable 7. Therefore, this plasticizer may be dissolved in the refrigerant R, and impurities such as the plasticizer may be eluted in the refrigerant R. The refrigerant R from which the impurities are eluted is mixed with the refrigerant R stored in the casing 23 from the cable inside the power supply 4, the power supply cable 5, and the communication cable 7. In this manner, impurities are mixed into the refrigerant R in the casing 23.

For a coating or the like of the power supply cable, for example, vinyl chloride or the like is used. When the vinyl chloride comes into contact with the refrigerant R, an oil component such as a phthalic acid ester, which is a plasticizer, is eluted into the refrigerant R. That is, examples of the impurities in the refrigerant R include oil components such as a phthalic acid ester.

### Condensation Unit

The condensation unit 22 is provided above the liquid level of the refrigerant

R in the casing 23. The condensation unit 22 condenses the evaporated refrigerant R in the casing 23. The condensation unit 22 is attached to the upper casing 25.

The condensation unit 22 according to the present embodiment is a water-cooled condenser. The condensation unit 22 includes a plurality of heat transfer tubes 27. Cooling water W circulates through the heat transfer tube 27. The condensation unit 22 performs heat exchange between the cooling water W and the gas-phase refrigerant R to condense the refrigerant R.

### Circulation Flow Channel

The circulation flow channel 11 is provided outside the casing 23. The circulation flow channel 11 is a pipe that circulates the refrigerant R inside. Both ends of the circulation flow channel 11 are connected to the casing 23 in a communication state. In the present embodiment, both ends of the circulation flow channel 11 are connected to the lower casing 24 in the casing 23. The circulation flow channel 11 is provided with the adsorption unit 12.

### Adsorption Unit

The adsorption unit 12 adsorbs impurities from the refrigerant R circulating in the circulation flow channel 11. The adsorption unit 12 according to the present embodiment is an adsorption tower having an adsorbent 12a that adsorbs impurities therein. The adsorbent 12a of the present embodiment is activated carbon. In addition, the adsorbent 12a is provided in an amount necessary for the impurity concentration in the refrigerant R, in which impurities have been adsorbed up to the upper limit of the adsorption amount of the adsorbent 12a, to reach the solubility of impurities in the refrigerant R after the temperature drop of the refrigerant R is completed. In addition, the expression “the impurity concentration reaches the target concentration of the solubility or the like” is not limited to a case where the impurity concentration and the solubility strictly match, and includes a case where the impurity concentration and the solubility are slightly different from each other. A method for calculating the required amount of the adsorbent 12a will be described in detail later.

### Pump

The pump 13 is provided in the circulation flow channel 11. The pump 13 pressurizes and feeds the refrigerant R in one direction in the circulation flow channel 11 to circulate the refrigerant R in the circulation flow channel 11. In the present embodiment, the pump 13 is disposed on the upstream side of the adsorption unit 12 in the circulation flow channel 11 in the circulation direction of the refrigerant R. The control device 30 is connected to the pump 13.

### Control Device

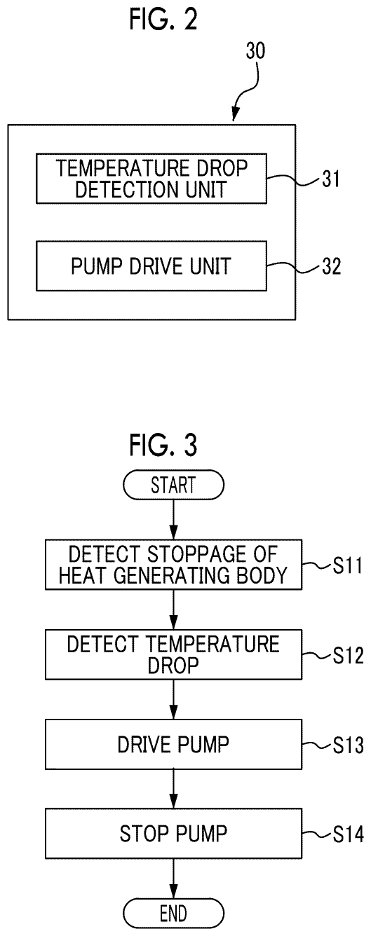

The control device 30 is a device that controls the driving of the pump 13 based on the temperature drop of the refrigerant R in the casing 23. The control device 30 according to the present embodiment is connected to the heat generating body 3. As shown in FIG. 2, the control device 30 includes a temperature drop detection unit 31 and a pump drive unit 32.

### Temperature Drop Detection Unit

The temperature drop detection unit 31 detects the decrease in temperature of the refrigerant R in the casing 23. In the present embodiment, the temperature drop detection unit 31 detects the temperature drop of the refrigerant R in the casing 23 by detecting the stoppage of the heat generating body 3.

### Pump Drive Unit

The pump drive unit 32 drives the pump 13 based on the detection of the temperature drop detection unit 31. In the present embodiment, in a case where the temperature drop detection unit 31 detects the stoppage of the heat generating body 3, the pump drive unit 32 drives the pump 13.

### Method for Removing Impurities

Meanwhile, during the generation of heat in the heat generating body 3, the impurities are eluted into the refrigerant R from the power supply cable 5 and the like, and the impurities in the refrigerant R are in a saturated state. The saturated state referred to herein is not only a case where the impurity concentration and the solubility strictly match, but also a case where the impurity concentration and the solubility are slightly different from each other.

When the refrigerant R is cooled, the solubility of impurities in the refrigerant R decreases. In this case, the impurities dissolved in the refrigerant R may be precipitated by cooling the refrigerant R. In a case where impurities are precipitated on the heat generating body 3 or the substrate 2, which is a cooling target, heat exchange between the refrigerant R and the heat generating body 3 is hindered by the precipitated impurities. Therefore, it is necessary to remove impurities to the extent that the impurities do not precipitate on the heat generating body 3 or the substrate 2 when the refrigerant R is cooled.

Hereinafter, a method for appropriately removing the impurities from the refrigerant R will be described with reference to FIG. 3.

In the present embodiment, by detecting the stoppage of the heat generating body 3 (step S11), the temperature drop detection unit 31 detects the decrease in temperature of the refrigerant R in the casing 23 (step S12).

Then, the pump drive unit 32 drives the pump 13 (step S13). In a case where the pump 13 is driven, the refrigerant R in the casing 23 is drawn into the circulation flow channel 11. The refrigerant R drawn into the circulation flow channel 11 circulates in the circulation flow channel 11 in the pressure feeding direction of the pump 13. As a result, the refrigerant R circulates inside the cycle of the casing 23 and the circulation flow channel 11. While the pump 13 is being driven, the refrigerant R passes through the adsorbent 12a in the adsorption unit 12. When the refrigerant R passes through the adsorbent 12a, the impurities in the refrigerant R are adsorbed on the adsorbent 12a. In this manner, the impurities are removed from the refrigerant R.

In addition, the flow rate of the pump 13 and the drive time of the pump 13 are set in the pump drive unit 32 before the operation of the liquid immersion cooling system 10. The setting of the flow rate of the pump 13 and the drive time of the pump 13 will be described in detail later.

In step S13, the pump 13 is driven until the impurity concentration in the refrigerant R in the casing 23 reaches the solubility of impurities after the temperature drop is completed. Then, the pump drive unit 32 stops the pump 13 (step S14), and the removal of the impurities in the refrigerant R is completed.

### Method for Calculating Required Amount of Adsorbent

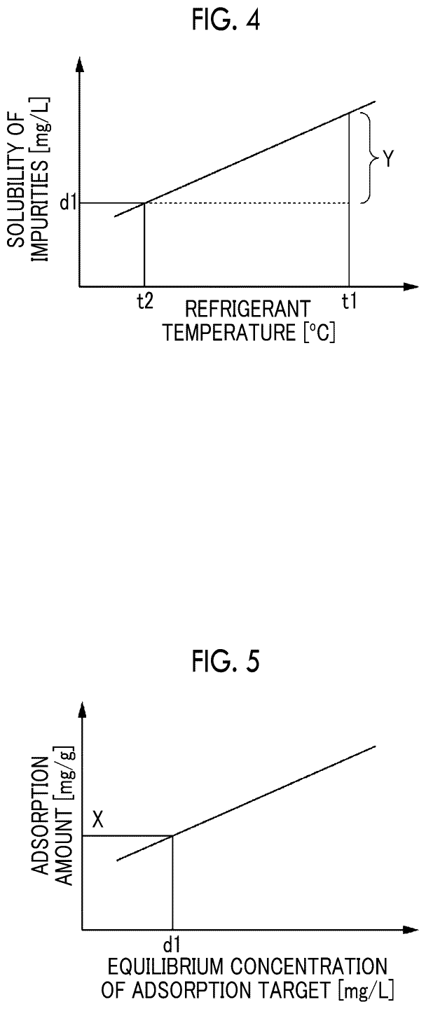

Subsequently, a method for calculating a required amount of the adsorbent 12a will be described with reference to FIGS. 4 and 5.

FIG. 4 is a graph showing a temperature change of the solubility of impurities. The horizontal axis of FIG. 4 indicates the refrigerant temperature [° C.]. The horizontal axis of FIG. 4 indicates a temperature of the refrigerant R before cooling as t1 [° C.] and indicates a temperature of the refrigerant R at the time of completion of cooling as t2 [° C.]. The vertical axis of FIG. 4 indicates the solubility [mg/L] of the impurities. As shown in FIG. 4, the solubility of impurities in the refrigerant R has a positive correlation with respect to the temperature of the refrigerant R.

It should be noted that the data in FIG. 4 is acquired by a pre-test before the operation of the liquid immersion cooling system 10.

Here, when the difference between the solubility of impurities at the temperature t1 [° C.] before the refrigerant R is cooled and the solubility of impurities at the temperature t2 [° C.] when the cooling of the refrigerant R is completed (hereinafter referred to as a removal target concentration d1 [mg/L]) is Y [mg/L], and the volume of the refrigerant R in the casing 23 is V [L], the amount of impurities to be removed a [mg] required to reliably bring the impurity concentration in the refrigerant R to the removal target concentration d1 [mg/L] is calculated by the following Formula (1).

$$α = Y \cdot V \qquad ( 1 )$$

The required amount of the adsorbent 12a is calculated based on the value of α [mg] calculated by Formula (1). Calculation of the required amount of the adsorbent 12a based on the value of a [mg] will be described with reference to FIG. 5.

FIG. 5 is a graph showing the adsorption capacity of the adsorbent 12a. The horizontal axis of FIG. 5 indicates the equilibrium concentration [mg/L] of the adsorption target that is dissolved in the solvent passing through the adsorbent 12a. The vertical axis of FIG. 5 indicates the adsorption capacity [mg/g]. The adsorption capacity [mg/g] is the amount [mg] of the adsorption target adsorbed per 1 [g] of the adsorbent 12a. As shown in FIG. 5, the adsorption capacity [mg/g] has a positive correlation with the equilibrium concentration [mg/L] of the adsorption target dissolved in the solvent passing through the adsorbent 12a.

The graph in FIG. 5 is an adsorption isotherm acquired when the solvent is at the temperature t2. FIG. 5 shows the adsorption capacity of the adsorbent 12a with respect to the equilibrium concentration [mg/L] of various solutions in which the adsorption target of the adsorbent 12a is dissolved. The horizontal axis of FIG. 5 indicates the removal target concentration d1 [mg/L]. The adsorption capacity X [mg/g] on the vertical axis of FIG. 5 corresponding to the removal target concentration d1 [mg/L] on the horizontal axis of FIG. 5 is the adsorption capacity X [mg/g] with respect to the impurities dissolved in the refrigerant R of the present embodiment at the temperature t2.

It should be noted that the data in FIG. 5 is acquired by the pre-test before the operation of the liquid immersion cooling system 10 similar to the data in FIG. 4.

Here, when the required amount of the adsorbent 12a is β [g], β [g] is calculated by the following Formula (2) based on the removal amount α [mg] of the impurities and the adsorption capacity X [mg/g].

$$β = α / X \qquad ( 2 )$$

As described above, the amount β [g] of the adsorbent 12a required to make the impurity concentration in the refrigerant R reach the removal target concentration d1 [mg/L] is calculated by using the simple Formula (1) and Formula (2) when the data of FIGS. 4 and 5 are acquired in advance.

### Setting of Flow Rate of Pump and Drive Time of Pump

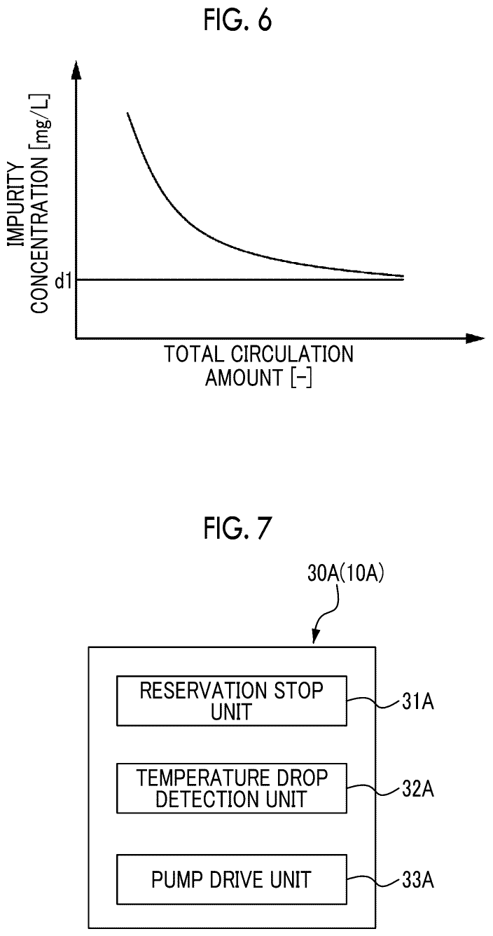

Subsequently, the setting of the flow rate of the pump 13 and the drive time of the pump 13 will be described with reference to FIG. 6.

FIG. 6 is a graph showing a decrease in impurity concentration due to the driving of the pump 13. The horizontal axis of FIG. 6 indicates the total circulation amount of the refrigerant R to the adsorption unit 12. The total circulation amount is the product of the flow rate [L/min] of the pump 13 and the drive time [min] of the pump 13. The value on the horizontal axis of FIG. 6 is standardized by dividing the total circulation amount by a volume V1 [L] of the adsorbent 12a. When the apparent density of the adsorbent 12a is represented by ρ [g/cm³], the volume V1 [L] of the adsorbent 12a is calculated by the following Formula (3).

$$V 1 = β / ρ / 1000 \qquad ( 3 )$$

In addition, the vertical axis of FIG. 6 indicates the impurity concentration [mg/L] in the refrigerant R.

It should be noted that the data in FIG. 6 is acquired by the pre-test before the operation of the liquid immersion cooling system 10 similar to the data in FIGS. 4 and 5.

As shown in FIG. 6, as the total circulation amount of the refrigerant R increases, the impurity concentration in the refrigerant R decreases and approaches the removal target concentration d1 [mg/L]. Based on the data in FIG. 6, the flow rate of the pump 13 and the drive time of the pump 13 are set such that the impurity concentration in the refrigerant R reaches the removal target concentration d1 [mg/L].

### Effects

The liquid immersion cooling system 10 according to the present embodiment exhibits the following effects.

In the present embodiment, the liquid immersion cooling system 10 includes the circulation flow channel 11, the adsorption unit 12, the pump 13, and the control device 30. The circulation flow channel 11 is connected in a state where both ends are in a communication state in the casing 23. The adsorption unit 12 is provided in the circulation flow channel 11 and adsorbs impurities from the refrigerant R circulating in the circulation flow channel 11. The pump 13 circulates the refrigerant R in the circulation flow channel 11. The control device 30 controls the pump 13. Further, the control device 30 includes the temperature drop detection unit 31 and the pump drive unit 32. The temperature drop detection unit 31 detects the decrease in temperature of the refrigerant R in the casing 23. The pump drive unit 32 drives the pump 13 based on the detection of the temperature drop detection unit 31.

With this, the liquid immersion cooling system 10 can drive the pump 13 in accordance with the decrease in temperature of the refrigerant R in the casing 23. Then, the refrigerant R in the casing 23 circulates in the circulation flow channel 11 and passes through the adsorption unit 12. Since the adsorption unit 12 adsorbs the impurities in the refrigerant R, the impurity concentration in the refrigerant R in the casing 23 is reduced. As a result, precipitation of impurities due to the temperature drop of the refrigerant R in the casing 23 is suppressed.

In addition, the pump 13 is not driven except for the case where the temperature of the refrigerant R in the casing 23 decreases, and the refrigerant R in the casing 23 is not supplied to the adsorption unit 12. Therefore, the decrease in impurity concentration in the refrigerant R in the casing 23 is suppressed except for the case of the temperature drop of the refrigerant R in the casing 23, and the impurities in the refrigerant R are maintained in a saturated state. Therefore, the liquid immersion cooling system 10 can suppress the elution of impurities from the power supply cable 5 and the like immersed in the refrigerant R while suppressing the precipitation of impurities due to the temperature drop of the refrigerant R. Therefore, the liquid immersion cooling system 10 can suppress deterioration of the power supply cable 5 and the like. Further, since it is not necessary to constantly drive the pump 13, a power cost for operating the pump 13 is reduced.

In addition, since the driving of the pump 13 is controlled by detecting the temperature drop of the refrigerant R, it is not necessary to provide a plurality of measurement equipment related to light transmission, infrared spectroscopy, conductivity, and the like. Further, measurement equipment for measuring the impurity concentration in the refrigerant R is not required. Therefore, the operation control of the liquid immersion cooling system 10 is simplified.

As described above, the liquid immersion cooling system 10 can efficiently remove the impurities in the refrigerant R.

In the present embodiment, the adsorption unit 12 has the adsorbent 12a that adsorbs impurities. The adsorbent 12a is provided in an amount necessary for the impurity concentration in the refrigerant R, in which impurities have been adsorbed up to the upper limit of the adsorption amount of the adsorbent 12a, to reach the solubility of impurities in the refrigerant R after the temperature drop of the refrigerant R is completed.

When the refrigerant R is continuously supplied to the adsorbent 12a by the pump 13, the adsorbent 12a adsorbs the impurities in the refrigerant R up to the upper limit of the adsorption amount. According to the present embodiment, in the liquid immersion cooling system 10, the impurity concentration in the refrigerant R can reach the solubility of impurities after the temperature drop of the refrigerant R in the casing 23 is completed simply by driving the pump 13 until the upper limit of the adsorption amount of the adsorbent 12a is reached. Accordingly, the liquid immersion cooling system 10 can easily saturate the impurities in the refrigerant R even in the case of the temperature drop of the refrigerant R. Therefore, the liquid immersion cooling system 10 can simply and reliably suppress the elution of impurities from the power supply cable 5 and the like immersed in the refrigerant R.

In the present embodiment, the temperature drop detection unit 31 detects the stoppage of the heat generating body 3. Further, in a case where the temperature drop detection unit 31 detects the stoppage of the heat generating body 3, the pump drive unit 32 drives the pump 13.

When the heat generating body 3 is stopped, heat is not supplied from the heat generating body 3 to the refrigerant R in the casing 23, and the temperature of the refrigerant R decreases. According to the present embodiment, the temperature drop detection unit 31 can detect the temperature drop caused by the stoppage of the heat generating body 3. Therefore, it is not necessary to provide measurement equipment such as a temperature sensor for detecting the temperature of the refrigerant R in the casing 23. As a result, the operation control of the liquid immersion cooling system 10 is further simplified.

### First Modification Example of First Embodiment

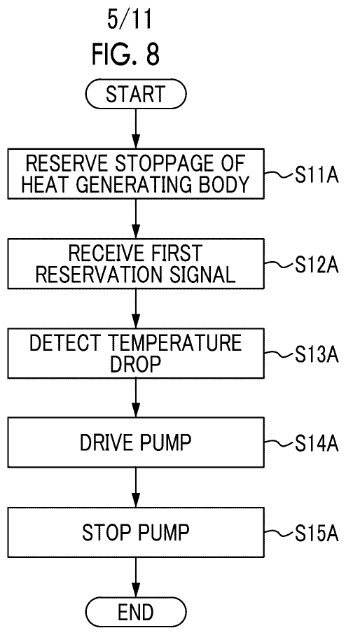

Next, a first modification example of the first embodiment will be described with reference to FIGS. 7 and 8.

As shown in FIG. 7, in a liquid immersion cooling system 10A of the present modification example, a control device 30A includes a reservation stop unit 31A, a temperature drop detection unit 32A, and a pump drive unit 33A.

The reservation stop unit 31A stops the heat generating body 3 after a predetermined time set in advance elapses. The reservation stop unit 31A transmits the first reservation signal to the temperature drop detection unit 32A before the heat generating body 3 is stopped. It should be noted that the setting of the stoppage reservation time of the heat generating body 3 in the reservation stop unit 31A may be performed each time the refrigerant R is cooled, may be performed during the manufacturing of the liquid immersion cooling system 10A, or may be performed during the maintenance of the liquid immersion cooling system 10A.

The temperature drop detection unit 32A detects that the temperature of the refrigerant R in the casing 23 will decrease in the future by receiving the first reservation signal. In a case where the temperature drop detection unit 32A receives the first reservation signal, the pump drive unit 33A drives the pump 13.

### Method for Removing Impurities

Next, a method for removing impurities according to the present modification example will be described with reference to FIG. 8.

In the present modification example, first, the reservation stop unit 31A reserves the stoppage of the heat generating body 3 (step S11A). Then, the first reservation signal is transmitted from the reservation stop unit 31A to the temperature drop detection unit 32A. By receiving the first reservation signal (step S12A), the temperature drop detection unit 32A detects the decrease in temperature of the refrigerant R in the casing 23 (step S13A).

Then, the pump drive unit 33A drives the pump 13 (step S14A). As a result, the refrigerant R circulates within the cycle of the casing 23 and the circulation flow channel 11, and the impurities in the refrigerant R are removed by the adsorbent 12a. Thereafter, the pump drive unit 33A stops the pump 13 (step S15A), and the removal of the impurities in the refrigerant R is completed.

The removal of impurities is started before the temperature of the refrigerant R decreases. The removal of the impurities may be completed during the decrease in temperature of the refrigerant R, but it is desirable to complete the removal of the impurities before the temperature of the refrigerant R decreases.

### Effects

According to the liquid immersion cooling system 10A of the present modification example, the following effects are exhibited.

In the present modification example, the control device 30A further includes the reservation stop unit 31A. The reservation stop unit 31A stops the heat generating body 3 after a predetermined time elapses, and transmits the first reservation signal to the temperature drop detection unit 32A before the heat generating body 3 is stopped. The temperature drop detection unit 32A detects that the temperature of the refrigerant R in the casing 23 will decrease in the future by receiving the first reservation signal. In a case where the temperature drop detection unit 32A receives the first reservation signal, the pump drive unit 33A drives the pump 13.

Accordingly, before the temperature of the refrigerant R decreases, the liquid immersion cooling system 10A can drive the pump 13 to remove the impurities from the refrigerant R in the casing 23. Therefore, the liquid immersion cooling system 10A can more reliably suppress the precipitation of impurities due to the temperature drop of the refrigerant R.

In addition, the control device 30A of the present modification example may use both a method in which the temperature drop detection unit 32A detects the stoppage of the heat generating body to detect the temperature drop of the refrigerant R and drive the pump 13 (the method disclosed in the flow of FIG. 3), and a method in which the temperature drop detection unit 32A detects the temperature drop of the refrigerant R by receiving the first reservation signal (the method disclosed in the flow of FIG. 8). In this case, the user of the control device 30A can select which method to use to drive the pump 13.

### Second Modification Example of First Embodiment

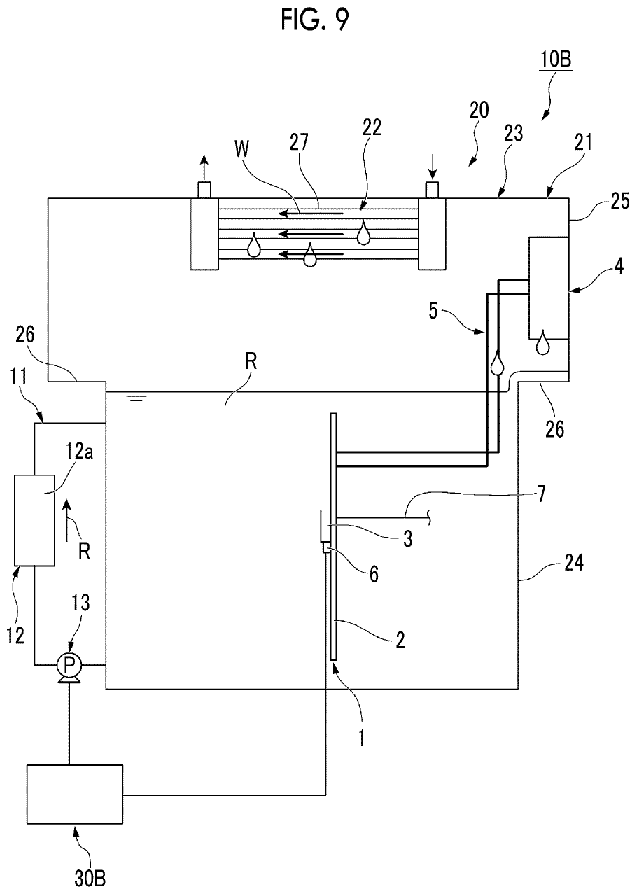

Next, a second modification example of the first embodiment will be described with reference to FIGS. 9 to 11.

As shown in FIG. 9, a liquid immersion cooling system 10B according to the present modification example further includes a heat generating body temperature sensor 6.

The heat generating body temperature sensor 6 measures the temperature of the heat generating body 3.

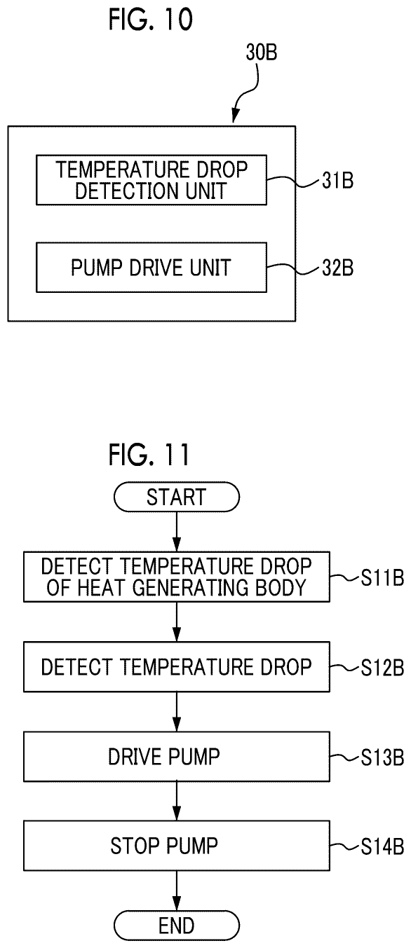

In addition, as shown in FIG. 10, in the liquid immersion cooling system 10B according to the present modification example, a control device 30B is connected to the heat generating body 3. The control device 30B includes a temperature drop detection unit 31B and a pump drive unit 32B.

The temperature drop detection unit 31B detects the temperature drop of the heat generating body 3 based on the detection result of the heat generating body temperature sensor 6. As the temperature drop detection unit 31B detects the temperature drop of the heat generating body 3, the pump drive unit 32B drives the pump 13.

### Method for Removing Impurities

Next, a method for removing impurities according to the present modification example will be described with reference to FIG. 11.

In the present modification example, the temperature drop detection unit 31B detects the temperature drop of the heat generating body 3 based on the detection result of the heat generating body temperature sensor 6 (step S11B). More specifically, the heat generating body temperature sensor 6 measures the temperature of the heat generating body 3 itself, and thus the temperature drop of the heat generating body 3 itself is detected. Then, the heat generating body temperature sensor 6 transmits the signal to the temperature drop detection unit 31B. The temperature drop detection unit 31B detects that the decrease in temperature of the refrigerant R in the casing 23 by receiving the signal from the heat generating body temperature sensor 6 (step S12B).

Then, the pump drive unit 32B drives the pump 13 (step S13B). As a result, the refrigerant R circulates within the cycle of the casing 23 and the circulation flow channel 11, and the impurities in the refrigerant R are removed by the adsorbent 12a. Then, the pump drive unit 32B stops the pump 13 (step S14B), and the removal of the impurities in the refrigerant R is completed.

### Effects

According to the liquid immersion cooling system 10B of the present modification example, the following effects are exhibited.

In the present modification example, the control device 30B further includes the heat generating body temperature sensor 6 that measures the temperature of the heat generating body 3. The temperature drop detection unit 31B detects the temperature drop of the heat generating body 3 based on the detection result of the heat generating body temperature sensor 6. As the temperature drop detection unit 31B detects the temperature drop of the heat generating body 3, the pump drive unit 32B drives the pump 13.

Accordingly, the temperature drop detection unit 31B can detect the temperature drop by the temperature drop of the heat generating body 3 itself. Therefore, the temperature drop detection unit 31B can more accurately detect that the temperature of the refrigerant R in the casing 23 will decrease in the future. Therefore, it is possible to improve the detection accuracy of the temperature drop of the refrigerant R in the casing 23 by the temperature drop detection unit 31B.

In addition, in the first embodiment, the casing 23 includes the lower casing 24, the upper casing 25, and the connecting wall 26, and a case where the opening area of the upper casing 25 is larger than the opening area of the lower casing 24 has been described. However, the present disclosure is not limited thereto. For example, the opening area of the upper casing 25 may be smaller than the opening area of the lower casing 24. In addition, for example, the casing 23 may be a cubic container that does not have the connecting wall 26.

### Second Embodiment

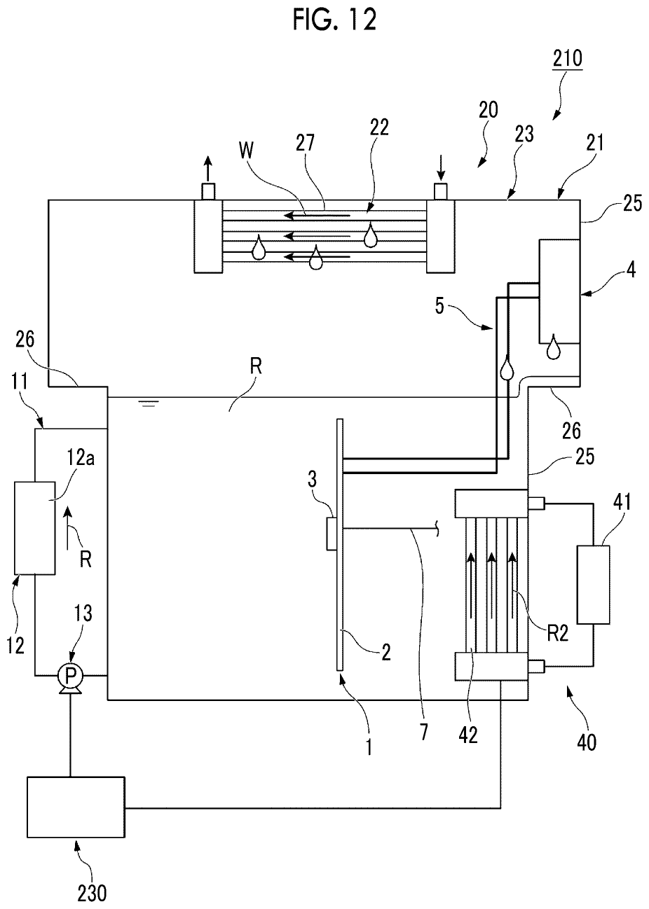

Hereinafter, a liquid immersion cooling system 210 according to the second embodiment of the present disclosure will be described with reference to FIGS. 12 to 14. The same configurations as those in the above-described first embodiment will be appropriately omitted by assigning the same names and the same reference numerals. As shown in FIG. 12, the liquid immersion cooling system 210 further includes a cooling unit 40.

### Cooling Unit

The cooling unit 40 cools the refrigerant R in the casing 23. The cooling unit 40 includes, for example, a chiller 41 and a cooling tube 42.

The chiller 41 is provided outside the casing 23.

The cooling tube 42 is provided in the lower casing 24. Both ends of the cooling tube 42 are connected to the chiller 41 in a communication state. A cycle through which the second refrigerant R2 circulates is formed by the cooling tube 42 and the chiller 41.

The second refrigerant R2 performs heat exchange with the liquid-phase refrigerant R in the casing 23 via the cooling tube 42 to cool the refrigerant R. The second refrigerant R2 is moved to the chiller 41 after being subjected to heat exchange with the refrigerant R. In the chiller 41, the second refrigerant R2 is radiated and cooled. The second refrigerant R2 cooled by the chiller 41 circulates through the cooling tube 42 again to perform heat exchange with the liquid-phase refrigerant R in the casing 23.

### Control Device

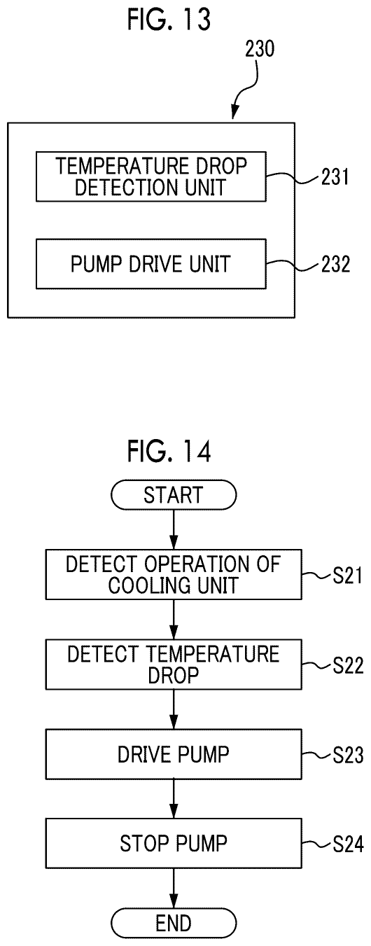

In addition, as shown in FIG. 13, a control device 230 according to the present embodiment includes a temperature drop detection unit 231 and a pump drive unit 232.

The temperature drop detection unit 231 detects the decrease in temperature of the refrigerant R in the casing 23 by detecting the operation of the cooling unit 40. In a case where the temperature drop detection unit 231 detects the operation of the cooling unit 40, the pump drive unit 232 drives the pump 13.

### Method for Removing Impurities

Next, a method for removing impurities according to the present embodiment will be described with reference to FIG. 14.

In the present embodiment, by detecting the operation of the cooling unit 40 (step S21), the temperature drop detection unit 231 detects the decrease in temperature of the refrigerant R in the casing 23 (step S22).

Then, the pump drive unit 232 drives the pump 13 (step S23). As a result, the refrigerant R circulates within the cycle of the casing 23 and the circulation flow channel 11, and the impurities in the refrigerant R are removed by the adsorbent 12a. Then, the pump drive unit 232 stops the pump 13 (step S24), and the removal of the impurities in the refrigerant R is completed.

### Effects

The liquid immersion cooling system 210 according to the present embodiment exhibits the following effects.

In the present embodiment, the liquid immersion cooling system 210 includes the cooling unit 40 that cools the refrigerant R in the casing 23.

As a result, the time required for cooling the refrigerant R in the casing 23 is shortened. Therefore, the time from the stoppage of the heat generating body 3 to the opening of the casing 23 is shortened. Therefore, the maintainability of the liquid immersion cooling system 210 can be improved.

In the present embodiment, the temperature drop detection unit 231 detects the operation of the cooling unit 40. Further, in a case where the temperature drop detection unit 231 detects the operation of the cooling unit 40, the pump drive unit 232 drives the pump 13.

Accordingly, the temperature drop detection unit 231 can detect the temperature drop caused by the stoppage of the heat generating body 3. Therefore, it is not necessary to provide measurement equipment such as a temperature sensor for detecting the temperature of the refrigerant R in the casing 23. As a result, the operation control of the liquid immersion cooling system 210 is further simplified.

### Modification Example of Second Embodiment

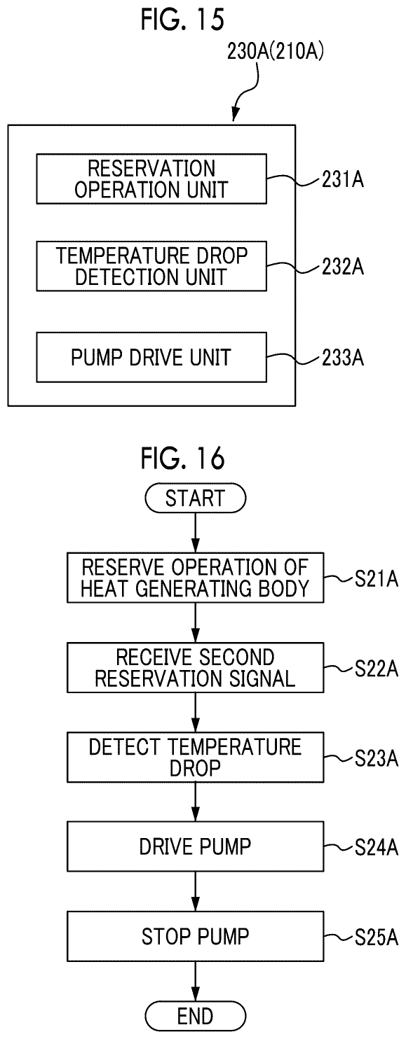

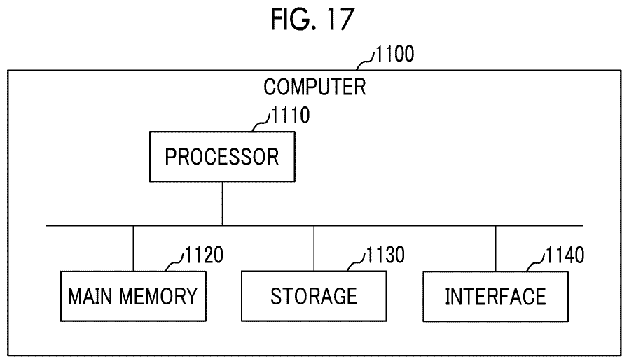

Next, a modification example of the second embodiment will be described with reference to FIGS. 15 and 16.

As shown in FIG. 15, in a liquid immersion cooling system 210A of the present modification example, a control device 230A includes a reservation operation unit 231A, a temperature drop detection unit 232A, and a pump drive unit 233A.

The reservation operation unit 231A operates the cooling unit 40 after a predetermined time set in advance elapses. The reservation operation unit 231A transmits the second reservation signal to the temperature drop detection unit 232A before the operation of the cooling unit 40. It should be noted that the setting of the operation reservation time of the cooling unit 40 in the reservation operation unit 231A may be performed each time the refrigerant R is cooled, may be performed during the manufacturing of the liquid immersion cooling system 210A, or may be performed during the maintenance of the liquid immersion cooling system 210A.

The temperature drop detection unit 232A detects that the temperature of the refrigerant R in the casing 23 will decrease in the future by receiving the second reservation signal. In a case where the temperature drop detection unit 232A receives the second reservation signal, the pump drive unit 233A drives the pump 13.

### Method for Removing Impurities

Next, a method for removing impurities according to the present modification example will be described with reference to FIG. 16.

In the present modification example, first, the reservation operation unit 231A reserves the operation of the cooling unit 40 (step S21A). Then, the second reservation signal is transmitted from the reservation operation unit 231A to the temperature drop detection unit 232A. By receiving the second reservation signal (step S22A), the temperature drop detection unit 232A detects the decrease in temperature of the refrigerant R in the casing 23 (step S23A).

Then, the pump drive unit 233A drives the pump 13 (step S24A). As a result, the refrigerant R circulates within the cycle of the casing 23 and the circulation flow channel 11, and the impurities in the refrigerant R are removed by the adsorbent 12a. Thereafter, the pump drive unit 233A stops the pump 13 (step S25A), and the removal of the impurities in the refrigerant R is completed.

The removal of impurities is started before the temperature of the refrigerant R decreases. The removal of the impurities may be completed during the decrease in temperature of the refrigerant R, but it is desirable to complete the removal of the impurities before the temperature of the refrigerant R decreases.

In addition, the control device 230A of the present modification example may use both a method in which the temperature drop detection unit 232A detects the operation of the cooling unit 40 to detect the temperature drop of the refrigerant R and drive the pump 13 (the method disclosed in the flow of FIG. 14), and a method in which the temperature drop detection unit 232A detects the temperature drop of the refrigerant R by receiving the second reservation signal (the method disclosed in the flow of FIG. 16). In this case, the user of the control device 230A can select which method to use to drive the pump 13.

### Hardware Configuration

The control devices 30, 30A, 230, and 230A of the respective embodiments and the respective modification examples described above are mounted in a computer 1100. The computer 1100 includes a processor 1110, a main memory 1120, a storage 1130, and an interface 1140.

In addition, the operation of each of the above-described processing units of the control devices 30, 30A, 30B, 230, and 230A is stored in the storage 1130 in a program format. The processor 1110 reads the program from the storage 1130, deploys the read program in the main memory 1120, and executes the above-described processing in accordance with the program. Further, the processor 1110 ensures a storage area corresponding to the above-described storage unit in the main memory 1120 in accordance with the program.

The program may be a program for realizing some of functions performed by the computer 1100. For example, the program may exhibit the function in combination with another program already stored in the storage 1130 or in combination with another program mounted on another device. In addition, the computer 1100 may include a custom large scale integrated circuit (LSI) such as a programmable logic device (PLD) in addition to or in place of the above configuration. Examples of the PLD include a programmable array logic (PAL), a generic array logic (GAL), a complex programmable logic device (CPLD), and a field-programmable gate array (FPGA). In this case, some or all of the functions realized by the processor 1110 may be realized by the integrated circuit.

As an example of the storage 1130, a magnetic disk, a magneto-optical disk, or a semiconductor memory can be used. The storage 1130 may be an internal medium directly connected to a bus of the computer 1100 or may be an external medium connected to the computer 1100 through the interface 1140 or a communication line. In addition, when this program is distributed to the computer 1100 via the communication line, the computer 1100 receiving the distributed program may deploy the program in the main memory 1120 to execute the above-described processing. The storage 1130 may be a non-temporary tangible storage medium.

In addition, the program may be a program for realizing some of the above-described functions.

In addition, the program may be a so-called difference file (difference program) that realizes the above-described functions in combination with another program previously stored in the storage 1130.

### Other Embodiments

Above, the embodiments of the present disclosure have been described in detail with reference to the drawings, but the specific configuration is not limited to the embodiments, and includes design changes and the like within a scope not departing from the gist of the present disclosure.

For example, the liquid immersion cooling systems 10, 10A, and 10B of the first embodiment may be applied to the cooling unit 40 and the control devices 230 and 230A of the second embodiment, and the control of the pump 13 based on the stoppage of the heat generating body 3 or the temperature drop detection of the heat generating body 3 itself and the control of the pump 13 based on the operation of the cooling unit 40 may be used in combination.

In addition, the adsorbent 12a of the present embodiment is activated carbon, but the present invention is not limited thereto. The adsorbent 12a can be appropriately changed according to the impurities which are the adsorption targets.

In addition, in the above embodiment, the case where the temperature drop of the refrigerant R in the casing 23 is detected based on the stoppage of the heat generating body 3 or the temperature drop detection of the heat generating body 3 itself, or the case where the temperature drop of the refrigerant R in the casing 23 is detected based on the operation of the cooling unit 40 has been described, but the present disclosure is not limited thereto. For example, the liquid immersion cooling systems 10, 10A, 10B, 210, and 210A may include a temperature sensor that measures the temperature of the refrigerant R in the casing 23. In this case, the temperature drop detection units 31, 32A, 31B, 231, and 232A can also detect that the temperature of the refrigerant R in the casing 23 decreases in a case where the temperature of the refrigerant R in the casing 23 measured by the temperature sensor is lower than a predetermined temperature set in advance.

In addition, in the above-described embodiment, the refrigerant in the liquid immersion cooling systems 10, 10A, 10B, 210, and 210A does not need measurement equipment for measuring the impurity concentration in the refrigerant R, but the present disclosure is not limited thereto. The liquid immersion cooling systems 10, 10A, 10B, 210, and 210A may include measurement equipment that measures the impurity concentration in the refrigerant R. In this case, the liquid immersion cooling systems 10, 10A, 10B, 210, and 210A drive the pump 13 to remove the impurities in the refrigerant R until the impurity concentration obtained by the measurement equipment reaches the solubility of impurities when the cooling of the refrigerant R is completed.

### Additional Note

The liquid immersion cooling systems 10, 10A, 10B, 210, and 210A, and the removal method described in each embodiment are understood as follows, for example.
(1) According to a first aspect, there is provided a liquid immersion cooling system 10, 10A, 10B, 210, or 210A, which is a liquid immersion cooling system 10, 10A, 10B, 210, or 210A that cools a heat generating body 3 provided on a substrate 2, the liquid immersion cooling system including: a cooling device main body 21 having a casing 23 that houses the substrate 2 and the heat generating body 3 inside and stores a refrigerant R for cooling the heat generating body 3; a circulation flow channel 11 having both ends connected to each other in a communication state in the casing 23; an adsorption unit 12 that is provided in the circulation flow channel 11 and adsorbs impurities from the refrigerant R circulating in the circulation flow channel 11; a pump 13 that circulates the refrigerant R in the circulation flow channel 11; and a control device 30, 30A, 30B, 230, or 230A that controls the pump 13, in which the control device 30, 30A, 30B, 230, or 230A includes a temperature drop detection unit 31, 32A, 31B, 231, or 232A that detects a decrease in temperature of the refrigerant R in the casing 23, and a pump drive unit 32, 33A, 32B, 232, or 233A that drives the pump 13 based on a detection of the temperature drop detection unit 31, 32A, 31B, 231, or 232A.

Accordingly, the liquid immersion cooling systems 10, 10A, 10B, 210, and 210A can drive the pump 13 in accordance with the decrease in temperature of the refrigerant R in the casing 23. Then, the refrigerant R in the casing 23 circulates in the circulation flow channel 11 and passes through the adsorption unit 12. Since the adsorption unit 12 adsorbs the impurities in the refrigerant R, the impurity concentration in the refrigerant R in the casing 23 is reduced. As a result, precipitation of impurities due to the temperature drop of the refrigerant R in the casing 23 is suppressed.

In addition, the pump 13 is not driven except for the case where the temperature of the refrigerant R in the casing 23 decreases, and the refrigerant R in the casing 23 is not supplied to the adsorption unit 12. Therefore, the decrease in impurity concentration in the refrigerant R in the casing 23 is suppressed except for the case of the temperature drop of the refrigerant R in the casing 23, and the impurities in the refrigerant R are maintained in a saturated state. Further, the power cost for operating the pump 13 is reduced.

In addition, since the driving of the pump 13 is controlled by detecting the temperature drop of the refrigerant R, it is not necessary to provide a plurality of measurement equipment related to light transmission, infrared spectroscopy, conductivity, and the like.
(2) In the liquid immersion cooling system 10 according to a second aspect, which is the liquid immersion cooling system 10 of (1), the temperature drop detection unit 31 may detect stoppage of the heat generating body 3, and the pump drive unit 32 may drive the pump 13 in a case where the temperature drop detection unit 31 detects the stoppage of the heat generating body 3.

Accordingly, the temperature drop detection unit 31 can detect the temperature drop caused by the stoppage of the heat generating body 3. Therefore, it is not necessary to provide measurement equipment such as a temperature sensor for detecting the temperature of the refrigerant R in the casing 23.
(3) In the liquid immersion cooling system 10A according to a third aspect, which is the liquid immersion cooling system 10A of (1) or (2), the control device 30A may further include a reservation stop unit 31A that stops the heat generating body 3 after a predetermined time elapses and that transmits a first reservation signal to the temperature drop detection unit 32A before the heat generating body 3 is stopped, the temperature drop detection unit 32A may detect that a temperature of the refrigerant R in the casing 23 will decrease in the future by receiving the first reservation signal, and the pump drive unit 33A may drive the pump 13 in a case where the temperature drop detection unit 32A receives the first reservation signal.

Accordingly, before the temperature of the refrigerant R decreases, the liquid immersion cooling system 10A can drive the pump 13 to remove the impurities from the refrigerant R in the casing 23.
(4) In the liquid immersion cooling system 10B according to a fourth aspect, which is the liquid immersion cooling system 10B of any one of (1) to (3), a heat generating body temperature sensor 6 that detects a temperature of the heat generating body 3 may further be provided, the temperature drop detection unit 31B may detect a temperature drop of the heat generating body 3 based on a detection result of the heat generating body temperature sensor 6, and the pump drive unit 32B may drive the pump 13 in a case where the temperature drop detection unit 31B detects the temperature drop of the heat generating body 3.

Accordingly, the temperature drop detection unit 31B can detect the temperature drop by the temperature drop of the heat generating body 3 itself. Therefore, the temperature drop detection unit 31B can more accurately detect that the temperature of the refrigerant R in the casing 23 will decrease in the future.
(5) In the liquid immersion cooling system 210 or 210A according to a fifth aspect, which is the liquid immersion cooling system 210 or 210A of any one of (1) to (4), a cooling unit 40 that cools the refrigerant R in the casing 23 may further be provided.

As a result, the time required for cooling the refrigerant R in the casing 23 is shortened. Therefore, the time from the stoppage of the heat generating body 3 to the opening of the casing 23 is shortened.
(6) In the liquid immersion cooling system 210 according to a sixth aspect, which is the liquid immersion cooling system 210 of (5), the temperature drop detection unit 231 may detect an operation of the cooling unit 40, and the pump drive unit 232 may drive the pump 13 in a case where the temperature drop detection unit 31 detects the operation of the cooling unit 40.

According to the present aspect, the temperature drop detection unit 231 can detect the temperature drop by the operation of the cooling unit 40. Therefore, it is not necessary to provide measurement equipment such as a temperature sensor for detecting the temperature of the refrigerant R in the casing 23.
(7) In the liquid immersion cooling system 210A according to a seventh aspect, which is the liquid immersion cooling system 210A of (5) or (6), the control device 230A may further include a reservation operation unit 231A that operates the cooling unit 40 after a predetermined time elapses and that transmits a second reservation signal to the temperature drop detection unit 232A before the operation of the cooling unit 40, the temperature drop detection unit 232A may detect that a temperature of the refrigerant R in the casing 23 will decrease in the future by receiving the second reservation signal, and the pump drive unit 233A may drive the pump 13 in a case where the temperature drop detection unit 232A receives the second reservation signal.

Accordingly, before the temperature of the refrigerant R decreases, the liquid immersion cooling system 210A can drive the pump 13 to remove the impurities from the refrigerant R in the casing 23.
(8) According to an eighth aspect, there is provided a removal method, which is a removal method for removing impurities from a refrigerant R used in a liquid immersion cooling system 10, 10A, 10B, 210, or 210A that cools a heat generating body 3 provided on a substrate 2, in which the liquid immersion cooling system 10, 10A, 10B, 210, or 210A includes a cooling device main body 21 having a casing 23 that houses the substrate 2 and the heat generating body 3 inside and stores the refrigerant R, a circulation flow channel 11 having both ends connected to each other in a communication state in the casing 23, an adsorption unit 12 that is provided in the circulation flow channel 11 and adsorbs the impurities from the refrigerant R circulating in the circulation flow channel 11, and a pump 13 that circulates the refrigerant R in the circulation flow channel 11, and the method includes: a step S12, S13A, S12B, S22, or S23A of detecting a decrease in temperature of the refrigerant R in the casing 23, and a step S13, S14A, S13B, S23, or S24A of driving the pump 13 based on a detection of the decrease in temperature of the refrigerant R in the casing 23.

### INDUSTRIAL APPLICABILITY

The present invention can be used for a liquid immersion cooling system that cools a heat generating body provided on a substrate and a removal method for removing impurities from a refrigerant used for the liquid immersion cooling system that cools the heat generating body provided on the substrate.

### REFERENCE SIGNS LIST

1: Server
2: Substrate
3: Heat generating body
4: Power supply
5: Power supply cable
6: Heat generating body temperature sensor
7: Communication cable
10: Liquid immersion cooling system
11: Circulation flow channel
12: Adsorption unit
12a: Adsorbent
13: Pump
20: Cooling device
21: Cooling device main body
22: Condensation unit
23: Casing
24: Lower casing
25: Upper casing
26: Connecting wall
27: Heat transfer tube
30: Control device
31: Temperature drop detection unit
32: Pump drive unit
R: Refrigerant
W: Cooling water
10A: Liquid immersion cooling system
30A: Control device
31A: Reservation stop unit
32A: Temperature drop detection unit
30B: Control device
31B: Temperature drop detection unit
32B: Pump drive unit
33A: Pump drive unit
210: Liquid immersion cooling system
40: Cooling unit
41: Chiller
42: Cooling tube
230: Control device
231: Temperature drop detection unit
232: Pump drive unit
R2: Second refrigerant
210A: Liquid immersion cooling system
230A: Control device
231A: Reservation operation unit
232A: Temperature drop detection unit
233A: Pump drive unit
1100: Computer
1110: Processor
1120: Main memory
1130: Storage
1140: Interface

1. A liquid immersion cooling system that cools a heat generating body provided on a substrate, the liquid immersion cooling system comprising:
a cooling device main body having a casing that houses the substrate and the heat generating body inside and stores a refrigerant for cooling the heat generating body;
a circulation flow channel having both ends connected to each other in a communication state in the casing;
an adsorption unit that is provided in the circulation flow channel and adsorbs impurities from the refrigerant circulating in the circulation flow channel;
a pump that circulates the refrigerant in the circulation flow channel; and
a control device that controls the pump, wherein the control device includes
a temperature drop detection unit that detects a decrease in temperature of the refrigerant in the casing, and
a pump drive unit that drives the pump based on a detection of the temperature drop detection unit.

2. The liquid immersion cooling system according to claim 1, wherein
the temperature drop detection unit detects stoppage of the heat generating body, and
the pump drive unit drives the pump in a case where the temperature drop detection unit detects the stoppage of the heat generating body.

3. The liquid immersion cooling system according to claim 1, wherein
the control device further includes a reservation stop unit that stops the heat generating body after a predetermined time elapses and that transmits a first reservation signal to the temperature drop detection unit before the heat generating body is stopped,
the temperature drop detection unit detects that a temperature of the refrigerant in the casing will decrease in the future by receiving the first reservation signal, and
the pump drive unit drives the pump in a case where the temperature drop detection unit receives the first reservation signal.

4. The liquid immersion cooling system according to claim 1, further comprising:
a heat generating body temperature sensor that detects a temperature of the heat generating body, wherein
the temperature drop detection unit detects a temperature drop of the heat generating body based on a detection result of the heat generating body temperature sensor, and
the pump drive unit drives the pump in a case where the temperature drop detection unit detects the temperature drop of the heat generating body.

5. The liquid immersion cooling system according to claim 1, further comprising:
a cooling unit that cools the refrigerant in the casing.

6. The liquid immersion cooling system according to claim 5, wherein
the temperature drop detection unit detects an operation of the cooling unit, and
the pump drive unit drives the pump in a case where the temperature drop detection unit detects the operation of the cooling unit.

7. The liquid immersion cooling system according to claim 5, wherein
the control device further includes a reservation operation unit that operates the cooling unit after a predetermined time elapses and that transmits a second reservation signal to the temperature drop detection unit before the operation of the cooling unit,
the temperature drop detection unit detects that a temperature of the refrigerant in the casing will decrease in the future by receiving the second reservation signal, and
the pump drive unit drives the pump in a case where the temperature drop detection unit receives the second reservation signal.

8. A removal method for removing impurities from a refrigerant used in a liquid immersion cooling system that cools a heat generating body provided on a substrate, wherein
the liquid immersion cooling system includes
a cooling device main body having a casing that houses the substrate and the heat generating body inside and stores the refrigerant,
a circulation flow channel having both ends connected to each other in a communication state in the casing,
an adsorption unit that is provided in the circulation flow channel and adsorbs the impurities from the refrigerant circulating in the circulation flow channel, and
a pump that circulates the refrigerant in the circulation flow channel, and the method comprises:
a step of detecting a decrease in temperature of the refrigerant in the casing, and
a step of driving the pump based on a detection of the decrease in temperature of the refrigerant in the casing.
